(19) United States
(12) Patent Application Publication
(10) Pub. No.: US 2024/0274566 A1
(43) Pub. Date: Aug. 15, 2024

(54) PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Chia-Ling Lee, Hsinchu County (TW)

(73) Assignee: Powertech Technology Inc., Hsinchu County (TW)

(21) Appl. No.: 18/432,081

(22) Filed: Feb. 5, 2024

Related U.S. Application Data
(60) Provisional application No. 63/445,729, filed on Feb. 15, 2023.

(30) Foreign Application Priority Data
Nov. 16, 2023 (TW) 112144365

(51) Int. Cl. H01L 23/00

(52) U.S. Cl. CPC H01L 24/20; H01L 23/3121; H01L 23/3135; H01L 23/3185; H01L 24/19; H01L 23/293; H01L 2224/19; H01L 2224/2101; H01L 2224/2105; H01L 2224/211; H01L 2224/214

(57) ABSTRACT

A package structure includes a chip and a dielectric. The chip includes a chip connector disposed on an active surface of the chip. The dielectric is at least disposed on the active surface of the chip. The chip connector has a top surface and a side surface connected to the top surface. The dielectric does not directly cover part of the side surface close to the top surface.

### CROSS-REFERENCE TO RELATED APPLICATION

This application claims the priority benefit of U.S. provisional application Ser. No. 63/445,729, filed on Feb. 15, 2023 and Taiwan application serial no. 112144365, filed on Nov. 16, 2023. The entirety of the above-mentioned patent applications are hereby incorporated by reference herein and made a part of this specification.

### BACKGROUND

### Technical Field

The disclosure relates to a package structure and a manufacturing method thereof, and in particular to a package structure including at least one chip and a corresponding dielectric and a manufacturing method thereof.

### Description of Related Art

Modern electronic apparatus usually includes a corresponding chip. In the manufacturing process of the electronic apparatus, it is usually necessary to package the corresponding chip and connect each of the terminals of the chip to a corresponding circuit.

The number of terminals and/or the density of terminals of the chip may increase with the advancement of the manufacturing technology of chip. Therefore, in the manufacturing process of electronic apparatus, the subsequent packaging process and/or the corresponding circuit connection process also become more and more complex. For this reason, how to simplify the overall manufacturing method and/or achieve a higher yield has become a research topic.

### SUMMARY

The disclosure provides a package structure and a manufacturing method thereof, which simplify the manufacturing and/or achieve a high yield.

A package structure according to an embodiment of the disclosure includes a chip and a dielectric. The chip includes a chip connector disposed on an active surface. The dielectric is at least disposed on the active surface of the chip. The chip connector has a top surface and a side surface connected to the top surface. The dielectric does not directly cover part of the side surface close to the top surface.

A package structure according to an embodiment of the disclosure includes a chip, a dielectric, and a redistribution layer structure. The chip includes a semiconductor substrate and a chip connector disposed on the semiconductor substrate. The dielectric is at least disposed on the chip. The redistribution layer structure is disposed on the chip and the dielectric. A contact point where the chip connector, the dielectric, and the redistribution layer structure directly contact with each other is located on part of an outer planar surface of the chip connector.

A manufacturing method of a package structure according to an embodiment of the disclosure includes the following: providing a chip, including a chip connector, in which the chip connector has a top surface and a side surface connected to the top surface; forming a dielectric material on the chip to directly cover the chip; and forming a dielectric by removing part of the dielectric material to at least expose part of the side surface close to the top surface.

Based on the above, the package structure and the manufacturing method thereof simplify the manufacturing and/or achieve a high yield.

### BRIEF DESCRIPTION OF THE DRAWINGS

FIGS. 1A to 1I are partial cross-sectional schematic diagrams of part of a manufacturing method of a package structure according to the first embodiment of the disclosure.

FIGS. 1J and 1K are partial cross-sectional schematic diagrams of a package structure according to the first embodiment of the disclosure.

FIG. 2 is a partial cross-sectional diagram of a package structure according to the second embodiment of the disclosure.

FIG. 3 is a partial cross-sectional diagram of a package structure according to the third embodiment of the disclosure.

FIG. 4 is a partial cross-sectional diagram of a package structure according to the fourth embodiment of the disclosure.

FIGS. 5A and 5B are partial cross-sectional diagrams of a package structure according to the fifth embodiment of the disclosure.

FIGS. 6A and 6B are partial cross-sectional diagrams of a package structure according to the sixth embodiment of the disclosure.

FIGS. 7A and 7B are partial cross-sectional diagrams of a package structure according to the seventh embodiment of the disclosure.

FIG. 8 is a partial cross-sectional diagram of a package structure according to the eighth embodiment of the disclosure.

FIG. 9 is a partial cross-sectional diagram of a package structure according to the ninth embodiment of the disclosure.

### DESCRIPTION OF THE EMBODIMENTS

The directional terms used herein (for example, up, down, right, left, front, back, top, and bottom) are only for referencing to the drawings and are not intended to imply absolute directions. In addition, for clarity, some devices, areas, components or film layers may be omitted in the drawings.

Unless otherwise specifically stated, the steps of any method described herein are not intended to be construed as requiring execution in a particular order.

The disclosure will be more comprehensively expounded with reference to the drawings of the embodiments. However, the disclosure may also be embodied in a variety of different forms and should not be limited to the embodiments described herein. The thickness, dimensions, or size of layers or areas in the drawings are enlarged for clarity. The same or similar reference numerals denote the same or similar devices, areas, components or film layers, which will not be reiterated one by one in the following paragraphs.

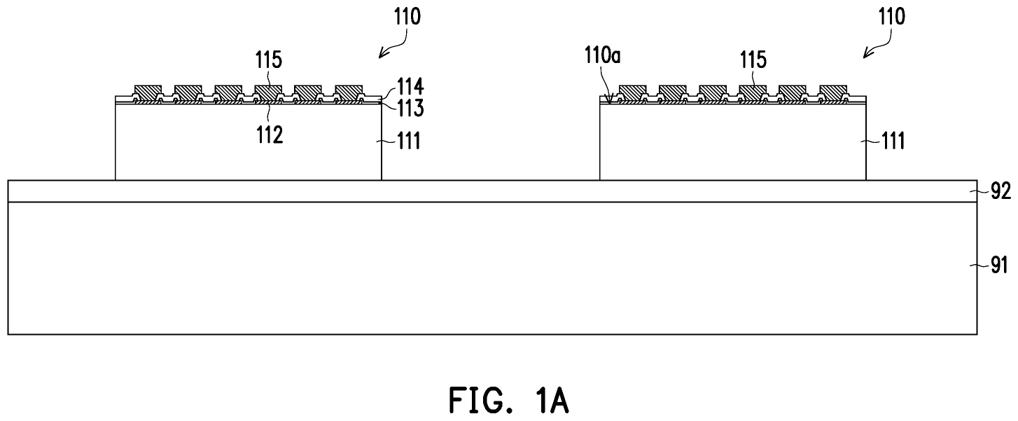

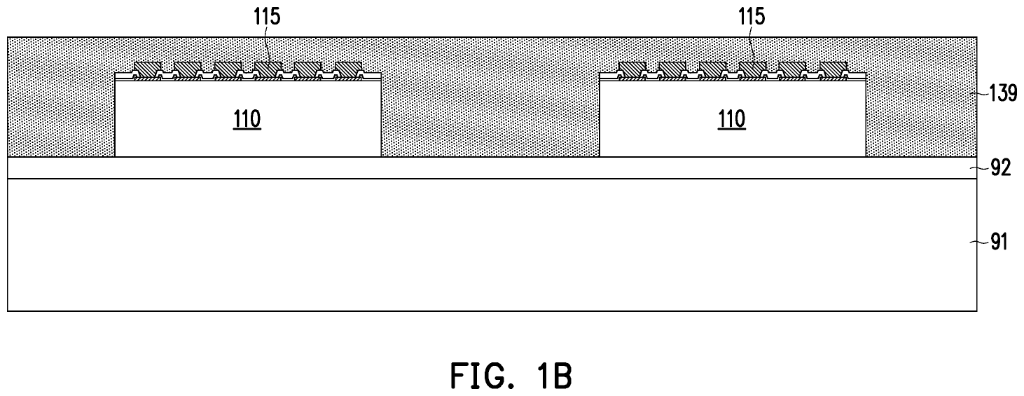

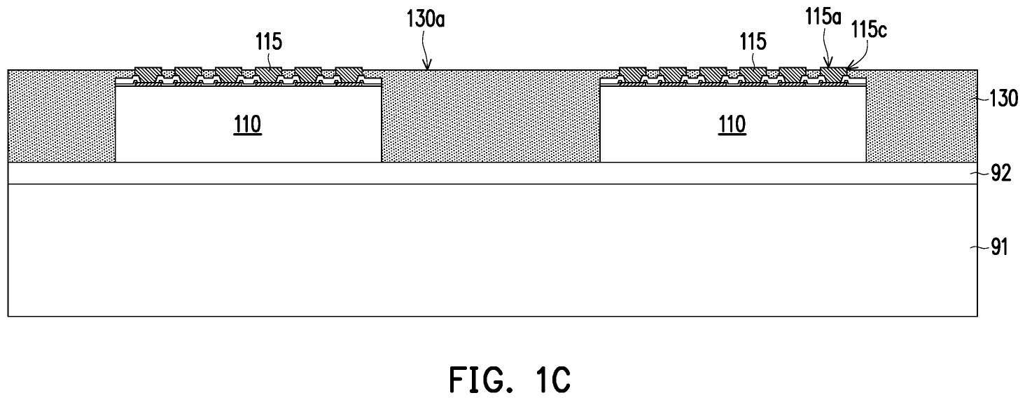

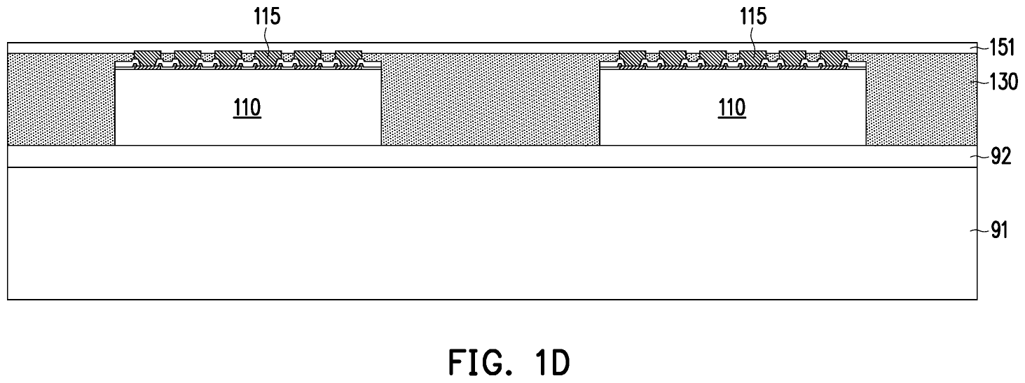

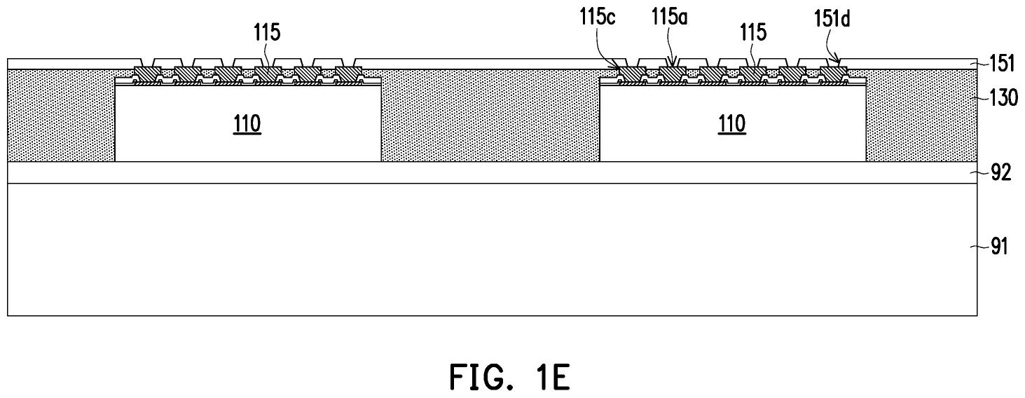

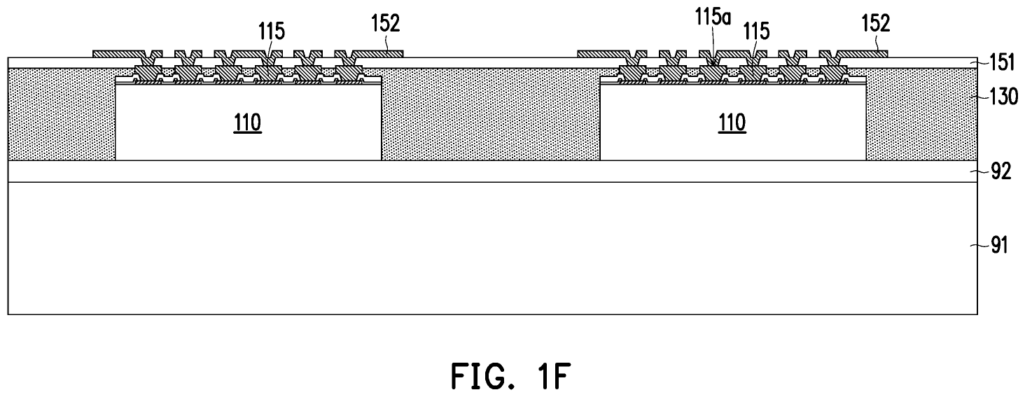

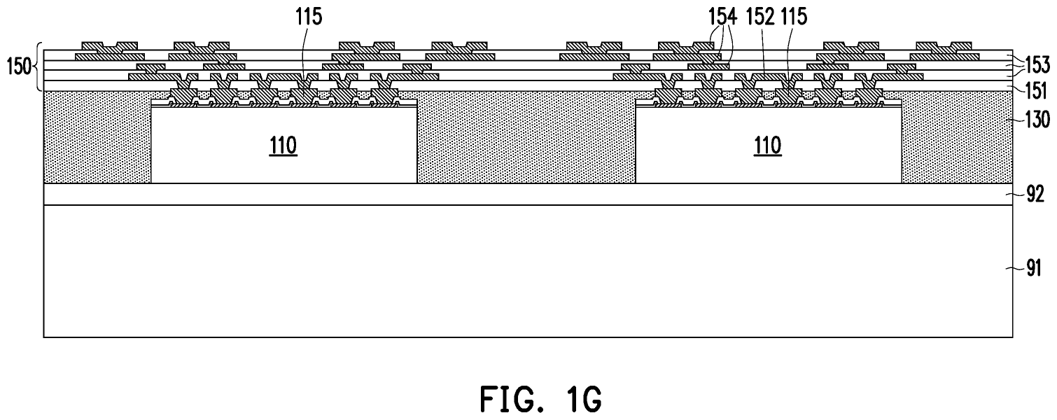

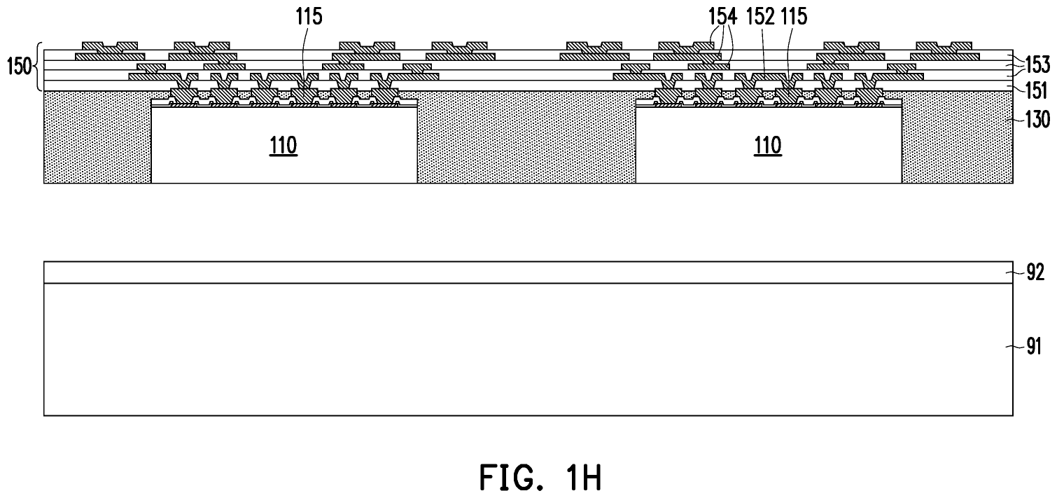

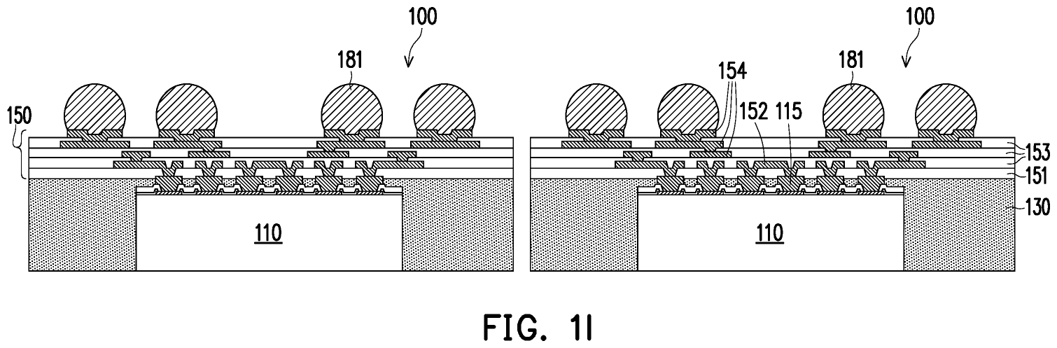

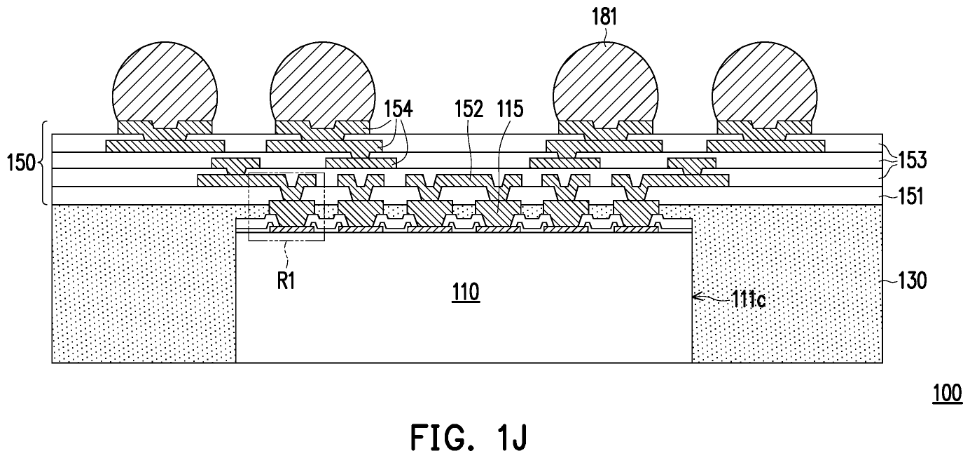

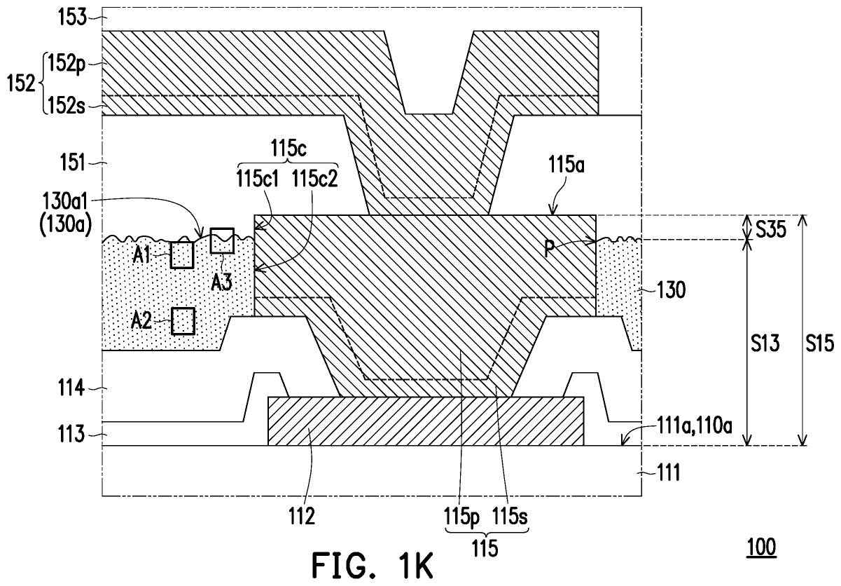

FIGS. 1A to 1I are partial cross-sectional schematic diagrams of part of a manufacturing method of a package structure according to the first embodiment of the disclosure. FIGS. 1J and 1K are partial cross-sectional schematic diagrams of a package structure according to the first embodiment of the disclosure. For example, FIG. 1K may be an enlarged diagram corresponding to an area R1 in FIG. 1J.

Referring to FIG. 1A, a chip 110 is provided. It is worth noting that only two chips 110 are exemplarily illustrated in FIG. 1A, but the disclosure does not limit a number, a type, and/or an arrangement of the provided chip 110.

In an embodiment, the chip 110 may be configured on a carrier 91. The carrier 91 may be made of glass, chip substrate, metal, or other suitable materials, as long as the materials may carry structures or components formed thereon in a subsequent manufacturing process.

In an embodiment, the carrier 91 may have a release layer 92. The release layer 92 may include a light to heat conversion (LTHC) adhesive layer, but the disclosure is not limited thereto.

In a possible embodiment (as described below, but not limited thereto), the carrier 91 may be provided with other components (such as heat dissipation members, electromagnetic interference (EMI) shielding components). The components may be disposed between the chip 110 and the carrier 91. The components may be in direct contact with the chip 110. The components may indirectly contact the chip 110; for example, there may be a corresponding adhesive layer (e.g., Die Attach Film (DAF)) between the components and the chip 110.

In the embodiment, the chip 110 may include a substrate 111, multiple connection pads 112, and multiple chip connectors 115. The substrate 111 may be a semiconductor substrate (e.g., a silicon substrate). A side of the substrate 111 has a device area (not shown), and a surface on which the device area is disposed may be referred an active surface 110a. The connection pad 112 may be disposed on the active surface 110a. The chip connector 115 may be disposed on the connection pad 112. In the design of the general chip 110, a device in the device area (e.g., the device in the device area of the chip 110) may be electrically connected to the corresponding connection pad 112 (e.g., part of the connection pad 112 of the chip 110) and the corresponding chip connector 115 (e.g., part of the chip connector 115 of the chip 110) through a corresponding back end of line interconnect (BEOL interconnect). In addition, for clarity, not all components or devices are marked one by one in FIG. 1A or other similar figures (e.g., each of the connection pads 112 or each of the chip connectors 115 is not marked one by one).

In the embodiment, the connection pad 112 is, for example, an aluminum pad or a copper pad, but the disclosure is not limited thereto.

In an embodiment, the connection pad 112 may be partially covered by an insulating layer 113, and the insulating layer 113 may expose part of the connection pad 112.

In an embodiment, a passivation layer 114 may cover the insulating layer 113, and the passivation layer 114 may expose part of the connection pad 112.

In an embodiment, the chip connector 115 may include a conductive pillar or a conductive bump.

In an embodiment, the chip connector 115 may be formed by a lithography process, a sputtering process, an electroplating process, and/or an etching process, but the disclosure is not limited thereto. For example, the chip connector 115 may include a first conductive layer 115s (marked in FIG. 1K) and a second conductive layer 115p (marked in FIG. 1K) disposed on the first conductive layer 115s, but the disclosure is not limited thereto. In a top view, patterns of the first conductive layer 115s and the second conductive layer 115p are substantially the same. In an embodiment, the first conductive layer 115s may be referred a seed layer. In an embodiment, the second conductive layer 115p may be referred a plating layer.

In an embodiment not shown, the chip connector (e.g., the chip connector similar to the chip connector 115) may include a pre-formed conductive member. For example, the chip connector may include a pre-formed conductive pillar, but the disclosure is not limited thereto.

In an embodiment, the chip connector 115 may correspond to an input/output terminal (I/O terminal), a power terminal, or a ground terminal of the chip 110.

Referring to FIGS. 1B and 1C, a dielectric 130 (marked in FIG. 1C) covering the chip 110 is formed. The dielectric 130 may expose part of the chip 110. For example, the dielectric 130 may expose the chip connector 115 of the chip 110.

In the embodiment, steps of forming the dielectric 130 are exemplified below.

Referring to FIG. 1B, a dielectric material 139 covering the chip 110 may be formed. In an embodiment, the dielectric material 139 is formed by, for example, a molding process, a coating process, or other suitable methods to form a polymer on the carrier 91. Then, a colloidal or molten high molecular polymer is solidified or semi-solidified. In an embodiment, the chip 110 may not be exposed outside the dielectric material 139, but the disclosure is not limited thereto.

In an embodiment, the dielectric material 139 is, for example, a molding compound. The molding compound may include, but are not limited to, an epoxy.

Referring to FIG. 1C, after the dielectric material 139 (marked in FIG. 1B) is formed, part of the dielectric material 139 (marked in FIG. 1B) may be removed to form the dielectric 130 (marked in FIG. 1C) laterally covering the chip 110. The dielectric 130 may expose a top surface 115a of the chip connector 115 and part of a side surface 115c close to the top surface 115a. In other words, part of the dielectric 130 close to the chip connector 115 is more concave than the chip connector 115.

In an embodiment, a thinning process may be conducted first to remove part of the dielectric material 139 (marked in FIG. 1B); and then, through the appropriate etching process, part of the side surface 115c of the chip connector 115 is exposed.

In an embodiment, the thinning process includes, for example, a chemical mechanical polishing (CMP), a mechanical grinding, the etching, or other suitable processes, but the disclosure is not limited thereto.

In an embodiment, after the thinning process and before the etching process, the top surface 115a of the chip connector 115 and the top surface of the thinned dielectric material 139 may be substantially coplanar.

In an embodiment, the etching process includes, for example, a dry etching process, a wet etching process, or other appropriate processes.

In an embodiment, the dry etching process may include, for example, an appropriate ashing process, a surface ablation process, or other appropriate processes. However, the disclosure is not limited thereto. The ashing process may include a plasma ashing process, and/or the surface ablation process may include a laser ablation process, but the disclosure is not limited thereto. In a possible embodiment, taking the dielectric material 139 including the polymer (such as the epoxy) as an example, after the dry etching process, a carbon element concentration of an area of the formed dielectric 130 close to the top surface 130a may be greater than a carbon element concentration of an area away from the top surface 130a. In a possible embodiment, the area of the dielectric 130 close to the top surface 130a may be embedded with corresponding carbon particles or carbon residue; and/or the top surface 130a of the dielectric 130 may have the corresponding carbon particles or the carbon residue.

In an embodiment, an etchant used in the wet etching process may be appropriately selected based on the properties of the dielectric material 139. Taking the epoxy as an example, methyl ethyl ketone (MEK) may be used as the etchant. Taking polyimide (PI) as an example, lactam may be used as the etchant.

In an embodiment, a space S35 (marked in FIG. 1K) between the top surface 115a of the chip connector 115 and the top surface 130a of the dielectric 130 may be about 0.5 micrometer (μm) to 2 micrometers.

In an embodiment, the etching process substantially does not affect an outer surface of the chip connector 115 (such as the top surface 115a; or the exposed part of the side surface 115c).

In an embodiment, a roughness of the top surface 115a of the chip connector 115 may be different from a roughness of the top surface 130a of the dielectric 130. In an embodiment, the top surface 130a of the dielectric 130 is rougher than the top surface 115a of the chip connector 115; that is, the roughness of the top surface 130a of the dielectric 130 is greater than the roughness of the top surface 115a of the chip connector 115.

In a possible embodiment, part of the dielectric material 139 (marked in FIG. 1B) may be directly removed through the etching process to form the dielectric 130 (marked in FIG. 1C) that laterally covers the chip 110.

Referring to FIGS. 1C to 1D, an insulating layer 151 may be formed on the chip connector 115 of the chip 110 and the dielectric 130 by coating, lamination, deposition or other appropriate methods. The material of the insulating layer 151 may include an organic material (such as polyimide) or an inorganic material (such as silicon oxide, silicon nitride, silicon oxynitride, other suitable materials, or a stack layer of at least two of the above materials).

Referring to FIGS. 1D to 1E, an insulating opening 151d exposing the chip connector 115 may be formed by etching or other appropriate methods. It is worth noting that the difference between the insulating layer 151 in FIG. 1E and the insulating layer 151 in FIG. 1D is substantially only the presence or absence of the insulating opening 151d, so the same symbols are used. In addition, for clarity, not all the insulation openings 151d are marked one by one in FIG. 1E or other similar drawings. In addition, the disclosure does not limit each of the chip connectors 115 to be exposed.

In an embodiment, an opening area of the insulating opening 151d may be less than a surface area of the top surface 115a of the chip connector 115. That is, the insulating opening 151d substantially does not expose all of the top surface 115a.

In the embodiment, the insulation opening 151d may only expose the top surface 115a of the corresponding chip connector 115. In an embodiment (such as the embodiment described below or the cross-sectional area not shown in the embodiment), an opening deviation (such as a displacement of an opening position, a change of an opening shape, and/or a change of an opening size) may be caused by a misalignment (such as an exposure misalignment and/or an etching misalignment), an over etching, or other possible factors. However, since part of the side surface 115c of the chip connector 115 close to the top surface 115a is not covered by the dielectric 130, even if there is the opening deviation, the impact on electrical properties may still be reduced (details thereof are as follows).

Referring to FIGS. 1E to 1F, after forming the insulating layer 151 having the insulating opening 151d (marked in FIG. 1E), a circuit layer 152 may be formed on the insulating layer 151. The circuit layer 152 may be formed by the lithography process, the sputtering process, the electroplating process, and/or an etching process. However, the disclosure is not limited thereto. A layout design of the circuit layer 152 may be adjusted according to actual needs, and is not limited by the disclosure. part of the circuit layer 152 may be filled into the insulating opening 151d to be electrically connected to the chip connector 115. The part of the circuit layer 152 filled into the insulating opening 151d may be referred a conductive via.

In an embodiment, the circuit layer 152 may include a first conductive layer 152s (shown in FIG. 1K) and a second conductive layer 152p (shown in FIG. 1K) disposed on the first conductive layer 152s. However, the disclosure is not limited thereto. In a top view, the patterns of the first conductive layer 152s and the second conductive layer 152p are substantially the same. In an embodiment, the first conductive layer 152s may be referred the seed layer. In an embodiment, the second conductive layer 152p may be referred the plating layer.

In the embodiment, the part of the circuit layer 152 filled into the insulating opening 151d may directly contact the top surface 115a of the chip connector 115. For example, part of the first conductive layer 152s (marked in FIG. 1K) filled into the insulating opening 151d may directly contact the top surface 115a of the chip connector 115. In an embodiment (such as the embodiment described later or the cross-sectional area not shown in the embodiment), if there is a phenomenon of the opening deviation, part of the circuit layer 152 filled into the insulating opening 151d may more directly contact part of the side surface 115c of the chip connector 115 close to the top surface 115a. In this way, the impact on the electrical properties may be reduced. That is to say, a greater process window may be provided, and the manufacturing of the package structure 100 (marked in FIG. 1J) may be simplified and/or achieve a high yield.

Referring to FIGS. 1F to 1G, in an embodiment, a corresponding insulating layer 153 and/or a corresponding circuit layer 154 may be formed at least on the chip 110 according to design requirements. The insulating layer 153 may be formed in the same or similar manner to the insulating layer 151. The circuit layer 154 may be formed in the same or similar manner to the circuit layer 152. In addition, the disclosure does not limit the number of layers of the insulating layer 153 and/or the circuit layer 154.

In an embodiment, the insulation layer 151, the circuit layer 152, the insulation layer 153, and/or the circuit layer 154 may be referred a redistribution layer structure (RDL structure) 150. The chip 110 may be electrically connected to a corresponding circuit in the redistribution layer structure 150 through the corresponding chip connector 115.

In an embodiment, the RDL structure 150 may be a fan out RDL structure. In an embodiment not shown, the RDL structure 150 may be a fan in RDL structure.

Referring to FIGS. 1G to 1H, the carrier 91 and the structure thereon are separated from each other. For example, light, heat or other appropriate methods may be used to reduce a bonding force of the release layer 92 (or any) to separate the carrier 91 and the structure thereon from each other by applying force.

Referring to FIGS. 1H to 1I, multiple conductive terminals 181 may be formed on the circuit layer 154 (which may be part of the RDL structure 150). The conductive terminals 181 may be electrically connected to the chip 110 through the corresponding circuit in the RDL structure 150. In addition, for clarity, not all conductive terminals 181 are marked one by one in FIG. 1I or other similar figures.

The conductive terminal 181 may be a conductive pillar, a solder ball, a conductive bump, or a conductive terminal having other forms or shapes. The conductive terminal 181 may be formed through the electroplating, the deposition, a ball placement, a reflow, and/or other appropriate processes.

Please continue to refer to FIG. 1I. In the embodiment, the package structures 100 may be formed through a singulation process. The singulation process may include, for example, a dicing process/cutting process to cut through the dielectric 130 and/or the RDL structure 150.

It is worth noting that after the singulation process is conducted, similar component symbols are used for the singulated components. For example, the chip 110 (as shown in FIG. 1H) may be the chip 110 (shown in FIG. 1I) after being singulated, the dielectric 130 (shown in FIG. 1H) may be the dielectric 130 after being singulated (as shown in FIG. 1I), the RDL structure 150 (as shown in FIG. 1H) may be the RDL structure 150 after being singulated (as shown in FIG. 1I), and the conductive terminals 181 (as shown in FIG. 1H) may be the conductive terminals 181 after being singulated (as shown in FIG. 1I), and so on. Other simplified components follow the same component notation rules mentioned above and will not be repeated or specifically illustrated here.

It is worth noting that the disclosure does not limit the order of removing the carrier 91 (if any), configuring the conductive terminals 181, and the singulation process (if necessary).

After the above processes, the package structure 100 of the embodiment is substantially manufactured.

Referring to FIGS. 1J and 1K, the package structure 100 includes the chip 110 and the dielectric 130. The chip 110 includes the chip connector 115. The dielectric 130 is at least disposed on the chip 110.

In the embodiment, the chip connector 115 may be disposed on the active surface 110a of the chip 110. The chip connector 115 may have the top surface 115a and the side surface 115c connected to the top surface 115a. The dielectric 130 may be at least disposed on the active surface 110a of the chip 110. The dielectric 130 may not directly cover and/or not directly contact part of a side surface 115c1 (i.e., a part of the side surface 115c that is closer to the top surface 115a). The dielectric 130 may directly cover and/or directly contact the remaining part of a side surface 115c2 (i.e., another part of the side surface 115c that is farther away from the top surface 115a). In an embodiment, the top surface 115a of the chip connector 115 may be substantially a planar surface.

In the embodiment, when viewed from a cross-section of the package structure 100 (as shown in FIGS. 1J and 1K), a slope of the side surface 115c of the chip connector 115 is substantially consistent. In an embodiment, the side surface 115c of the chip connector 115 is substantially a planar surface (e.g., an oblique planar surface or a vertical planar surface).

In the embodiment, the side surface 115c would be a cylindrical surface from a top view if the chip connector 115 is round shape.

In the embodiment, the chip 110 may further include the substrate 111. The substrate 111 may be the semiconductor substrate. The dielectric 130 may more directly cover and/or directly contact a side 111c of the substrate 111. In a thickness direction of the package structure 100, the top surface 115a of the chip connector 115 may be the outer surface of the chip connector 115 that is farthest away from the substrate 111; and/or, the dielectric 130 substantially may not be disposed between the chip connector 115 and the substrate 111.

In the embodiment, the chip connector 115 may include the first conductive layer 115s and the second conductive layer 115p disposed on the first conductive layer 115s, and the first conductive layer 115s is disposed between the second conductive layer 115p and the substrate 111. In an embodiment, the dielectric 130 may laterally completely directly cover and/or laterally completely directly contact the first conductive layer 115s.

In the embodiment, the top surface 130a of the dielectric 130 may have a first top surface area 130a1 extending away from the chip connector 115 from a contact point P of the first top surface area 130a1 and the chip connector 115. There may be the space S35 between the top surface 115a of the chip connector 115 and the first top surface area 130a1; and/or a roughness of the first top surface area 130a1 is different from a roughness of the top surface 115a of the chip connector 115.

In the embodiment, the package structure 100 may further include the RDL structure 150. The RDL structure 150 may be disposed on the chip 110 and the dielectric 130. The contact point P where the RDL structure 150 (such as the insulating layer 151 at the bottom), the chip connector 115, and the dielectric 130 directly contact with each other may be located on part of an outer planar surface (such as part of the side surface 115c) of the chip connector 115. That is to say, the contact point P is far away from and/or not located at an edge of the outer planar surface (such as the side surface 115c) where the contact point P is located. That is, the contact point P is not disposed at or away from an intersection of the side surface 115c and the top surface 115a. That is to say, there is a corresponding distance between the intersection of the side surface 115c and the top surface 115a and the contact point P. The outer planar surface where the contact point P is located may not be parallel to the top surface 111a of the substrate 111 or the active surface 110a of the chip 110.

In the embodiment, in the thickness direction of the package structure 100, at least part of the circuits in the RDL structure 150 do not overlap the chip 110; and/or, a distance S15 between the top surface 115a of the chip connector 115 and the substrate 111 is greater than a distance S13 between the contact point P and the substrate 111.

It is worth noting that in the cross-section (as shown in FIG. 1K or other similar figures), the contact point P is drawn in the form of a point. However, in actual three-dimensional objects, the contact point P may be a circular line. In addition, on the cross-section (as shown in FIG. 1K or other similar figures), there may be multiple contact points P, but for the simplicity of the illustration, not all the contact points P are marked one by one.

In an embodiment, in the thickness direction of the package structure 100, the carbon element concentration (such as a molar ratio of the carbon element) in an area A1 of the dielectric 130 close to the top surface 130a may be greater than the carbon element concentration in an area A2 far away from the top surface 130a. The carbon element concentration may be measured or observed, for example, by commonly used elemental analysis methods (such as energy-dispersive X-ray spectroscopy (EDX), but not limited thereto). However, the disclosure is not limited thereto.

In an embodiment, an interface area A3 between the dielectric 130 and the RDL structure 150 (in terms of measurement, may be the area including the same; for example: the area in the dielectric 130 close to the top surface 130a; and/or on the top surface 130a of the dielectric 130) may have the corresponding carbon particles or the carbon residue. The carbon particles or the carbon residue may be measured or observed by, for example, a scanning electron microscope (SEM), but the disclosure is not limited thereto.

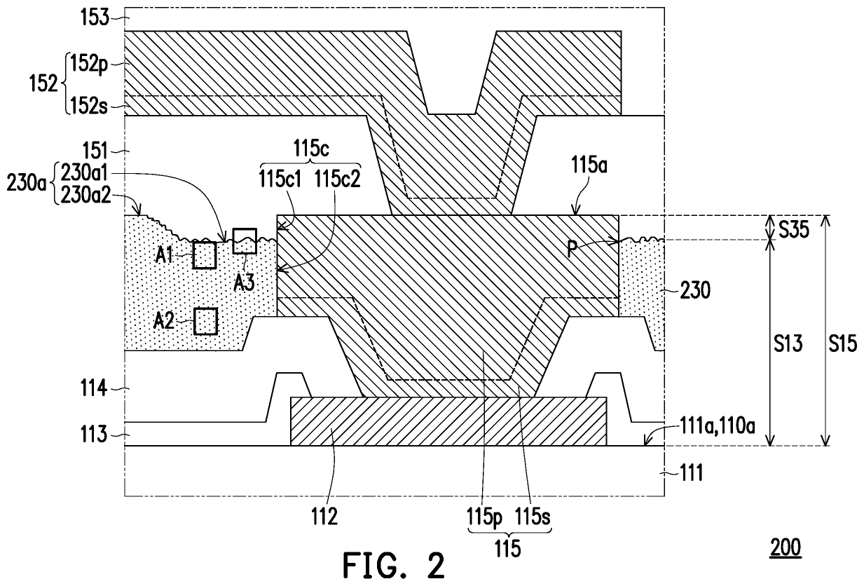

FIG. 2 is a partial cross-sectional diagram of a package structure according to the second embodiment of the disclosure. A package structure 200 and/or a manufacturing method thereof of the second embodiment are similar to the package structure 100 and/or the manufacturing method thereof of the first embodiment. Similar film layers, devices, components or areas are denoted by the same reference numerals and have similar functions, materials, or manners of formation, and the description is omitted. For example, FIG. 2 may be a schematic cross-sectional diagram similar to the area R1 in FIG. 1J.

Referring to FIG. 2, the package structure 200 includes the chip 110 and a dielectric 230. The dielectric 230 is at least disposed on the chip 110.

In the embodiment, a top surface 230a of the dielectric 230 may have a first top surface area 230a1 and a second top surface area 230a2. The first top surface area 230a1 extends from the contact point P of the first top surface area 230a1 and the chip connector 115 in a direction away from the chip connector 115. The second top surface area 230a2 is connected to the first top surface area 230a1. Moreover, the first top surface area 230a1 gradually approaches the second top surface area 230a2 from the contact point P of the first top surface area 230a1 and the chip connector 115; and/or, a vertical distance between the second top surface area 230a2 (or; a virtual surface extending therefrom) and the first top surface area 230a1 is substantially gradually decrease as from the contact point P of the first top surface area 230a1 and the chip connector 115 toward the second top surface area 230a2. That is to say, the first top surface area 230a1 is substantially not a planar surface. In other words, part of the dielectric 230 close to the chip connector 115 is more concave than the chip connector 115.

In an embodiment, the material and/or the formation method of the dielectric 230 may be similar to the material and/or the formation method of the dielectric 130. For example, in the process of forming the dielectric 230, the thinning process may be conducted first to remove part of the dielectric material 139 (marked in FIG. 1B); then, the dry etching process is conducted on the area near the chip connector 115 so that part of the side surface 115c of the chip connector 115 is exposed.

In the embodiment, there may be the space S35 between the first top surface area 230a1 and the top surface 115a of the chip connector 115; and/or, the roughness of the first top surface area 230a1 is different from the roughness of the top surface 115a of the chip connector 115.

In an embodiment, the top surface 115a of the chip connector 115 and the second top surface area 230a2 may be disposed on the same plane (i.e., coplanar); and/or, the roughness of the second top surface area 230a2 may be the same as or similar to the roughness of the top surface 115a of the chip connector 115.

In the embodiment, the package structure 200 may further include the RDL structure 150. The RDL structure 150 may be disposed on the chip 110 and the dielectric 230. The contact point P where the RDL structure 150 (such as the insulating layer 151 at the bottom), the chip connector 115, and the dielectric 230 directly contact with each other may be located on part of the outer planar surface of the chip connector 115 (such as part of the side surface 115c).

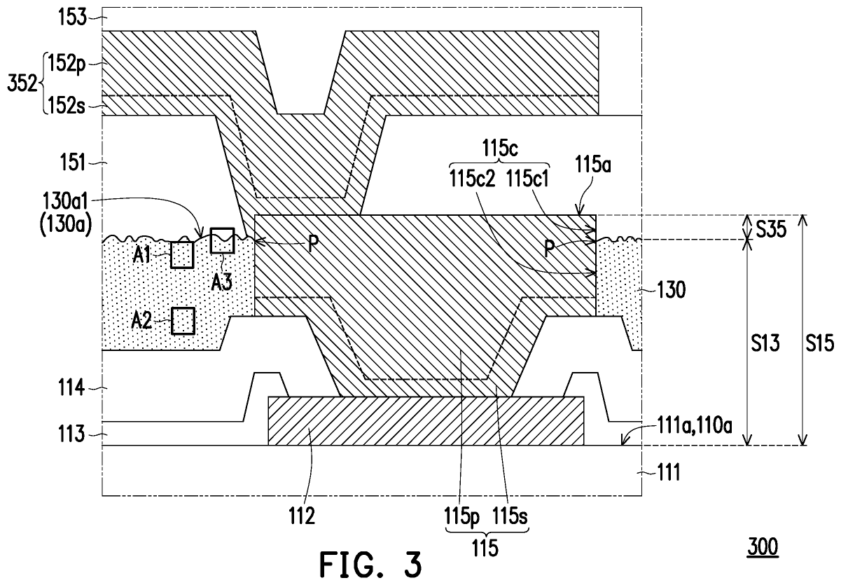

FIG. 3 is a partial cross-sectional diagram of a package structure according to the third embodiment of the disclosure. A package structure 300 and/or a manufacturing method thereof of the third embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, FIG. 3 may be a schematic cross-sectional diagram similar to the area R1 in FIG. 1J.

Referring to FIG. 3, the package structure 300 includes the chip 110, the dielectric 130 and the RDL structure 150. The RDL structure 150 may be disposed on the chip 110 and the dielectric 130. The contact point P between the RDL structure 150 (such as a circuit layer 352 at the bottom or the insulating layer 151 at the bottom), the chip connector 115, and the dielectric 130 directly contact with each other may be located on part of the outer planar surface of the chip connector 115 (e.g. part of the side surface 115c). The material and/or the formation method of the circuit layer 352 may be similar to the material and/or the formation method of the circuit layer 152.

In an embodiment, if there is a shift in the opening position during the formation of the insulating opening 151d, part of the circuit layer 352 filled into the insulating opening 151d may more directly contact part of the side surface 115c of the chip connector 115 close to the top surface 115a. In this way, the impact on the electrical performance may be reduced. That is to say, there may be the greater process window, and the manufacturing of the package structure 300 may be simplified and/or achieve a high yield.

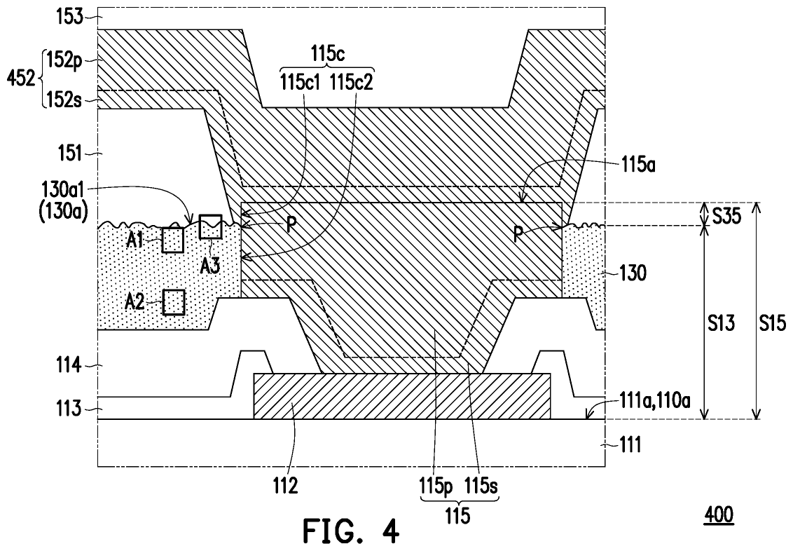

FIG. 4 is a partial cross-sectional diagram of a package structure according to the fourth embodiment of the disclosure. A package structure 400 and/or a manufacturing method thereof of the fourth embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, FIG. 4 may be a schematic cross-sectional diagram similar to the area R1 in FIG. 1J.

Referring to FIG. 4, the package structure 400 includes the chip 110, the dielectric 130, and the RDL structure 150. The RDL structure 150 may be disposed on the chip 110 and the dielectric 130. The contact point P where the RDL structure 150 (such as a circuit layer 452 at the bottom or the insulating layer 151 at the bottom), the chip connector 115, and the dielectric 130 directly contact with each other may be located on part of the outer planar surface of the chip connector 115 (e.g. part of the side surface 115c). The material and/or the formation method of the circuit layer 452 may be similar to the material and/or the formation method of the circuit layer 152.

In an embodiment, if there is a change in the shape of the opening and/or a change in the size of the opening during the formation of the insulating opening 151d; and/or, the insulating opening 151d has a larger size due to design requirements (such as: larger than the top surface 115a of the chip connector 115; similar to that shown in FIG. 4), part of the circuit layer 452 filled in the insulating opening 151d may more directly contact part of the side surface 115c of the chip connector 115 close to the top surface 115a, and surround the chip connector 115. In this way, the impact on the electrical performance may be reduced. That is to say, there may be the greater process window, and the manufacturing of the package structure 400 may be simplified and/or achieve a high yield.

It is worth noting that in the description of the disclosure, although FIG. 1J, FIG. 2, FIG. 3, and FIG. 4 are described with different embodiments, in terms of an overall structure of the package structure (similar to the package structure 100, the package structure 200, the package structure 300, or the package structure 400), the structures of which may still be included in the same package structure. For example, in a package structure of an embodiment not shown, the schematic cross-sectional diagram of one of the chip connectors 115 and the area nearby may be shown as one of FIG. 1J, FIG. 2, FIG. 3, and FIG. 4, and the schematic cross-sectional diagram of another chip connector 115 and the area nearby may be as shown as FIG. 1J, FIG. 2, FIG. 3, and FIG. 4. That is to say, two, three, or four of the corresponding structures as shown in FIG. 1J, FIG. 2, FIG. 3, and FIG. 4 may exist in the same package structure. For another example, in the package structure of an embodiment not shown, it is possible that due to opening deviation, different cross-sections of the same chip connector 115 may be as shown in one of FIG. 1J, FIG. 2, FIG. 3, and FIG. 4.

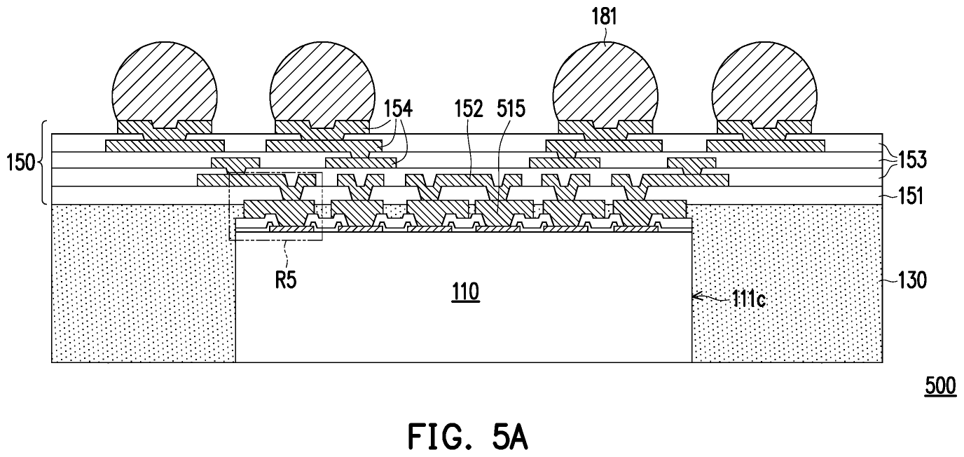

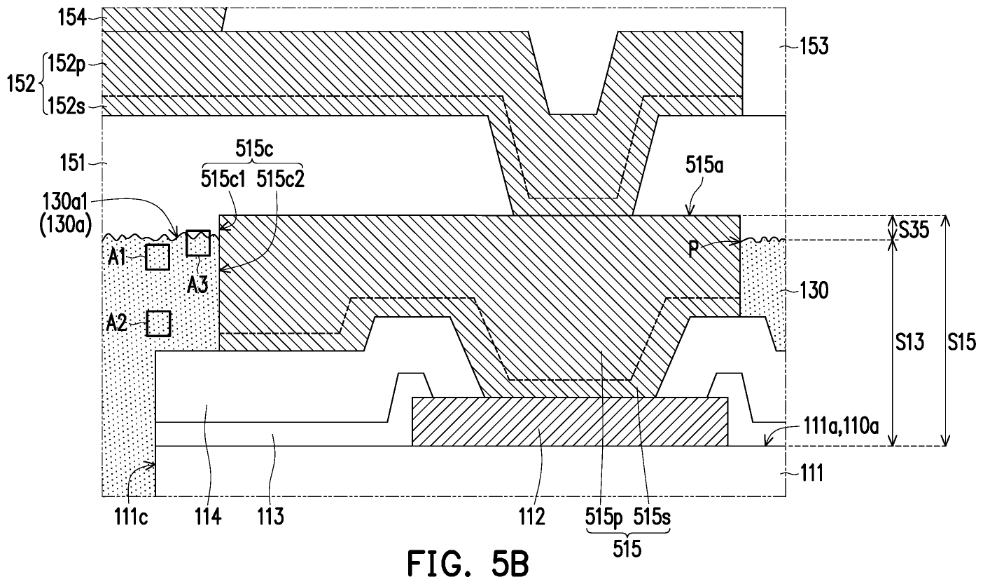

FIGS. 5A and 5B are partial cross-sectional diagrams of a package structure according to the fifth embodiment of the disclosure. A package structure 500 and/or a manufacturing method thereof of the fifth embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, FIG. 5B may be a enlarge diagram similar to an area R5 in FIG. 5A.

Referring to FIGS. 5A and 5B, the package structure 500 includes the chip 110 and the dielectric 130. The chip 110 includes a chip connector 515. The dielectric 130 is at least disposed on the chip 110.

In the embodiment, the chip connector 515 may have a top surface 515a and a side surface 515c connected to the top surface 515a. The chip connector 515 may be disposed on the active surface 110a of the chip 110. The dielectric 130 may not directly cover and/or directly contact part of a side surface 515c1 (i.e., part of the side surface 515c that is closer to the top surface 515a). The dielectric 130 may directly cover and/or directly contact the remaining part of a side surface 515c2 (i.e., another part of the side surface 515c that is further away from the top surface 515a). In an embodiment, the top surface 515a of the chip connector 515 may be substantially a planar surface.

In the embodiment, when viewed from a cross-section of the package structure 500 (as shown in FIGS. 5A and 5B), the slope of the side surface 515c of the chip connector 515 is substantially consistent. In an embodiment, the side surface 515c of the chip connector 515 is substantially a planar surface (e.g., an oblique planar surface or a vertical planar surface).

In the embodiment, in the thickness direction of the package structure 500, the top surface 515a of the chip connector 515 may be the outer surface of the chip connector 515 that is farthest away from the substrate 111; and/or, the dielectric 130 substantially may not be disposed between the chip connector 515 and the substrate 111.

In the embodiment, the chip connector 515 may include a first conductive layer 515s and a second conductive layer 515p disposed on the first conductive layer 515s, and the first conductive layer 515s is disposed between the second conductive layer 515p and the substrate 111. In an embodiment, the first conductive layer 515s may be referred the seed layer. In an embodiment, the second conductive layer 515p may be referred the plating layer.

In the embodiment, the top surface 130a of the dielectric 130 may have the first top surface area 130a1 extending away from the chip connector 515 from the contact point P of the first top surface area 130a1 and the chip connector 515. There may be the space S35 between the top surface 515a of the chip connector 515 and the first top surface area 130a1; and/or the roughness of the first top surface area 130a1 is different from the roughness of the top surface 515a of the chip connector 515.

In the embodiment, the contact point P where the RDL structure 150 (such as the insulating layer 151 at the bottom), the chip connector 515, and the dielectric 130 directly contact with each other may be located on part of the outer planar surface (such as part of the side surface 515c) of the chip connector 515. That is to say, the contact point P is far away from and/or not located at the edge of the outer planar surface (such as the side surface 515c) where the contact point P is disposed. The outer planar surface where the contact point P is located may not be parallel to the top surface 111a of the substrate 111 or the active surface 110a of the chip 110.

In the embodiment, in the thickness direction of the package structure 500, the distance S15 between the top surface 515a of the chip connector 515 and the substrate 111 is greater than the distance S13 between the contact point P and the substrate 111.

In the embodiment, in the thickness direction of the package structure 500, at least a part of a certain chip connector 515 may not overlap the connection pad 112, and the chip connector 515 may completely overlap the substrate 111. In an embodiment, the form of the chip connector 515 may be similar to the form of the circuit layers 152 and 154. In an embodiment, the chip connector 515 may be referred an on-chip RDL. In an embodiment, the chip connector 515 may be referred the fan in RDL. In an embodiment, the chip connector 515 may be referred an on-chip fan in RDL.

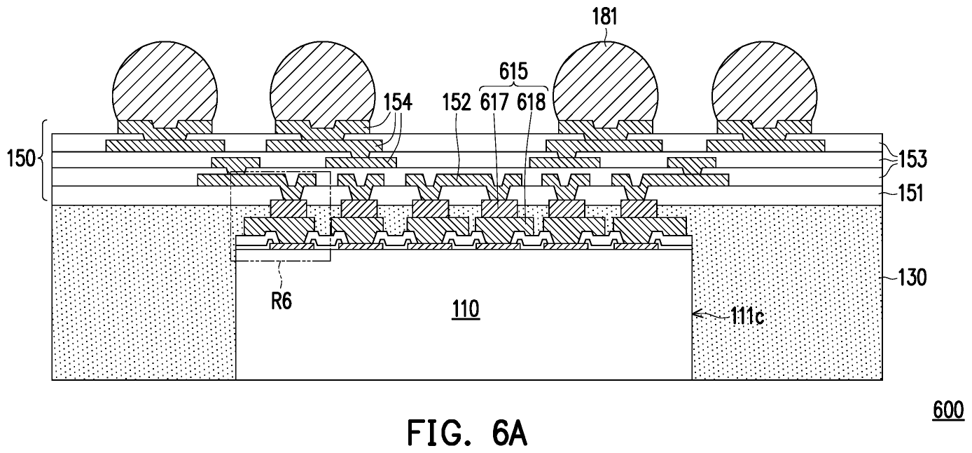

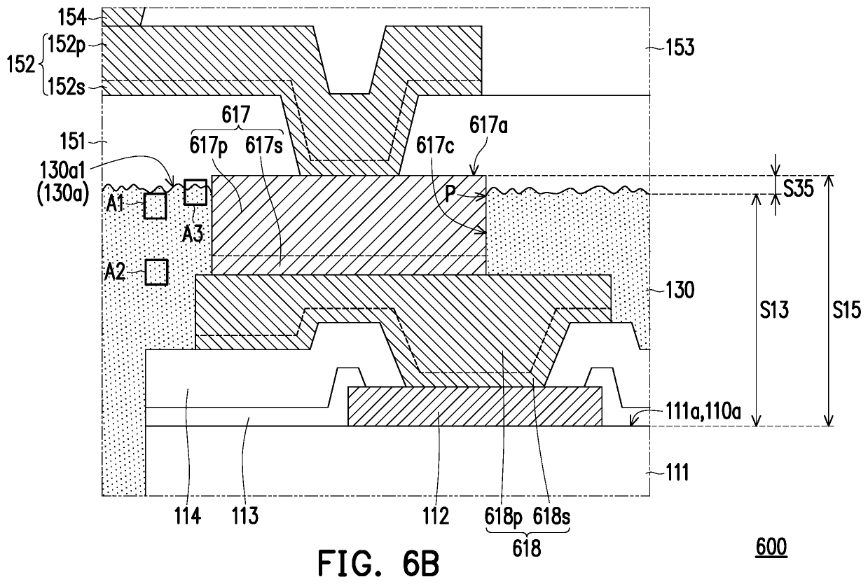

FIGS. 6A and 6B are partial cross-sectional diagrams of a package structure according to the sixth embodiment of the disclosure. A package structure 600 and/or a manufacturing method thereof of the sixth embodiment is similar to the package structure 100 and/or the manufacturing method thereof of the first embodiment and the package structure 500 and/or the manufacturing method thereof of the fifth embodiment. Similar film layers, devices, components or areas are denoted by the same reference numerals and have similar functions, materials, or manner of formation, and the description is omitted. For example, FIG. 6B may be a enlarge diagram similar to an area R6 in FIG. 6A.

Referring to FIGS. 6A and 6B, the package structure 600 includes the chip 110 and the dielectric 130. The chip 110 includes a chip connector 615. The dielectric 130 is at least disposed on the chip 110. The chip connector 615 may include a first chip connector 617 and a second chip connector 618. The connection pad 112 is electrically connected to the corresponding first chip connector 617 through the corresponding second chip connector 618.

In the embodiment, the first chip connector 617 may have a top surface 617a and a side surface 617c connected to the top surface 617a. The dielectric 130 may not directly cover and/or directly contact part of the side surface 617c close to the top surface 617a. The first chip connector 617 may be disposed on the active surface 110a of the chip 110. The top surface 617a of the first chip connector 617 may be substantially a planar surface. The dielectric 130 may directly cover and/or directly contact the remaining part of the side surface 617c away from the top surface 617a.

In the embodiment, when viewed from a cross-section of the package structure 600 (as shown in FIGS. 6A and 6B), the slope of the side surface 617c of the first chip connector 617 is substantially consistent. That is to say, the side surface 617c of the first chip connector 617 is substantially a planar surface (e.g., an oblique planar surface or a vertical planar surface).

In the embodiment, the side surface 617c would be a cylindrical surface from a top view if the first chip connector 617 is round shape.

In the embodiment, in the thickness direction of the package structure 600, the top surface 617a of the first chip connector 617 may be the outer surface of the first chip connector 617 that is farthest away from the substrate 111; and/or, the dielectric 130 may be substantially not disposed between the first chip connector 617 and the substrate 111. Also, the dielectric 130 may be substantially not disposed between the second chip connector 618 and the substrate 111.

In the embodiment, the first chip connector 617 may include a first conductive layer 617s and a second conductive layer 617p disposed on the first conductive layer 617s, and the first conductive layer 617s is disposed between the second conductive layer 617p and the substrate 111. The dielectric 130 may laterally completely directly cover and/or laterally completely directly contact the first conductive layer 617s. In an embodiment, the first conductive layer 617s may be referred the seed layer. In an embodiment, the second conductive layer 617p may be referred the plating layer.

In the embodiment, the second chip connector 618 may include a first conductive layer 618s and a second conductive layer 618p disposed on the first conductive layer 618s, and the first conductive layer 618s is disposed between the second conductive layer 618p and the substrate 111. The dielectric 130 may laterally completely directly cover and/or laterally completely directly contact the first conductive layer 618s and the second conductive layer 618p. In an embodiment, the first conductive layer 618s may be referred the seed layer. In an embodiment, the second conductive layer 618p may be referred the plating layer.

In the embodiment, the top surface 130a of the dielectric 130 may have a first top surface area 130a1 extending away from the first chip connector 617 from the contact point P of the first top surface area 130a1 and the first chip connector 617. There may be the space S35 between the top surface 617a of the first chip connector 617 and the first top surface area 130a1; and/or the roughness of the first top surface area 130a1 is different from the roughness of the top surface 617a of the first chip connector 617.

In the embodiment, the contact point P where the RDL structure 150 (such as the insulating layer 151 at the bottom), the first chip connector 617, and the dielectric 130 directly contact with each other may be located on part of the outer planar surface (such as part of the side surface 617c) of the first chip connector 617. That is to say, the contact point P is far away from and/or not located at the edge of the outer planar surface (such as the side surface 617c) where the contact point P is located. The outer planar surface where the contact point P is located may not be parallel to the top surface 111a of the substrate 111 or the active surface 110a of the chip 110.

In the embodiment, in the thickness direction of the package structure 600, the distance S15 between the top surface 617a of the first chip connector 617 and the substrate 111 is greater than the distance S13 between the contact point P and the substrate 111.

In the embodiment, in the thickness direction of the package structure 600, at least a part of the second chip connector 618 may not overlap the connection pad 112.

In an embodiment, the first chip connector 617 may be similar to the chip connector 115; and/or the second chip connector 618 may be similar to the chip connector 515.

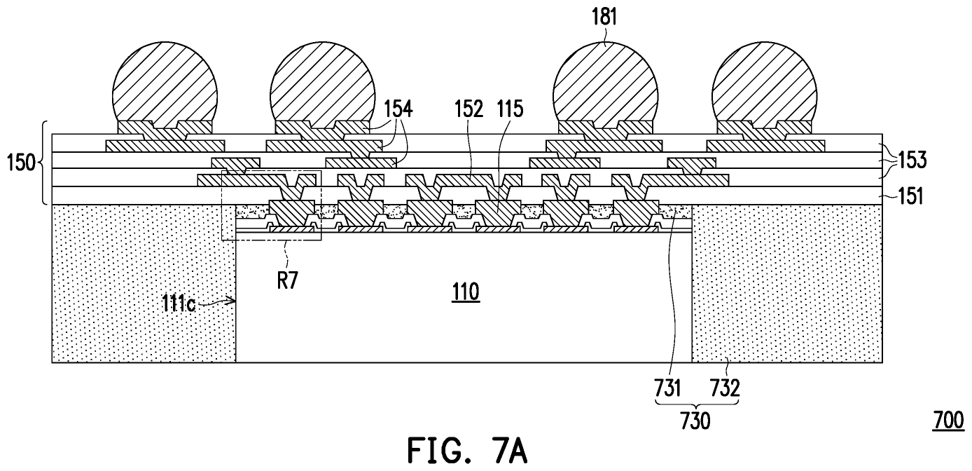

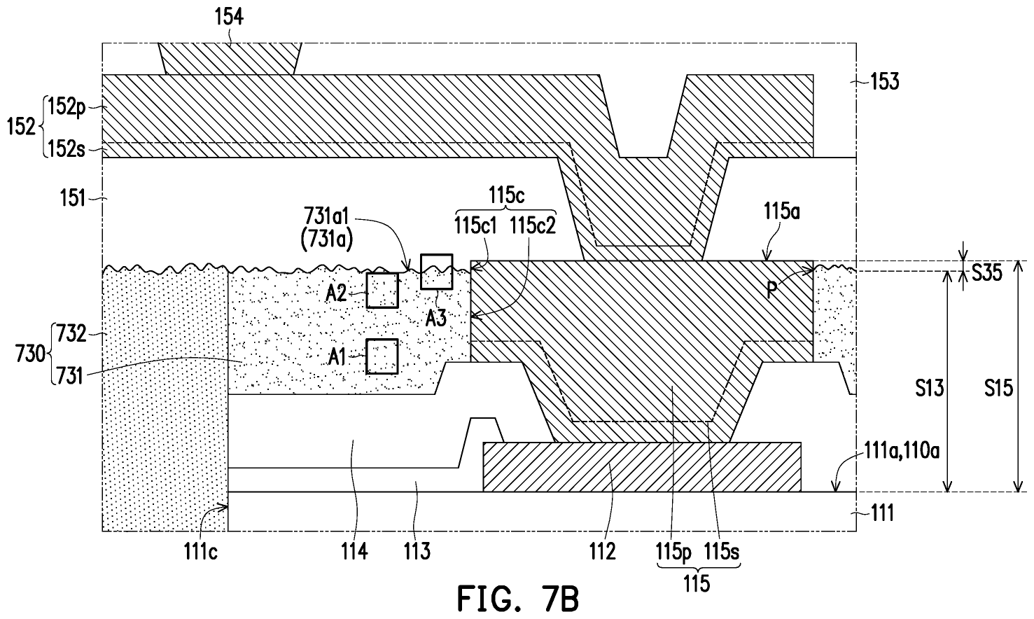

FIGS. 7A and 7B are partial cross-sectional diagrams of a package structure according to the seventh embodiment of the disclosure. A package structure 700 and/or a manufacturing method thereof of the seventh embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, FIG. 7B may be a enlarge diagram similar to an area R7 in FIG. 7A.

Referring to FIGS. 7A and 7B, the package structure 700 includes the chip 110 and a dielectric 730. The chip 110 includes the chip connector 115. The dielectric 730 may include a first dielectric 731 and a second dielectric 732. The first dielectric 731 is disposed at least on the active surface 110a of the chip 110.

In the embodiment, the material of the first dielectric 731 may be different from the material of the second dielectric 732. For example, the main material of the first dielectric 731 may be the polyimide (PI), and the main material of the second dielectric 732 may be the epoxy.

In the embodiment, the first dielectric 731 may be formed in the manner different from the second dielectric 732. For example, the first dielectric 731 may be formed by a film lamination process or the coating process, and the second dielectric 732 may be formed by the molding process.

In the embodiment, the first dielectric 731 may not directly cover and/or not directly contact part of the side surface 115c1 (i.e., a part of the side surface 115c that is closer to the top surface 115a); and/or, the first dielectric 731 may directly cover and/or directly contact the remaining part of the side surface 115c2 (i.e., another part of the side surface 115c that is farther away from the top surface 115a). That is to say, part of the dielectric 730 (e.g., part of the first dielectric 731) close to the chip connector 115 is more concave than the chip connector 115.

In the embodiment, the second dielectric 732 may more directly cover and/or directly contact the side surface 111c of the substrate 111. In the thickness direction of the package structure 700, the dielectric 730 may be substantially not disposed between the chip connector 115 and the substrate 111.

In the embodiment, the first dielectric 731 may laterally completely directly cover and/or laterally completely directly contact the first conductive layer 115s.

In the embodiment, the top surface 731a of the first dielectric 731 may have a first top surface area 731a1 extending away from the chip connector 115 from the contact point P of the first top surface area 731a1 and the chip connector 115. There may be the space S35 between the top surface 115a of the chip connector 115 and the first top surface area 731a1; and/or the roughness of the first top surface area 731a1 is different from the roughness of the top surface 115a of the chip connector 115.

In the embodiment, the contact point P where the RDL structure 150 (such as the insulating layer 151 at the bottom), the chip connector 115, and the first dielectric 731 directly contact with each other may be located on part of the outer planar surface (such as part of the side surface 115c) of the chip connector 115. That is to say, the contact point P is far away from and/or not located at the edge of the outer planar surface (such as the side surface 115c) where the contact point P is located. The outer planar surface where the contact point P is located may not be parallel to the top surface 111a of the substrate 111 or the active surface 110a of the chip 110.

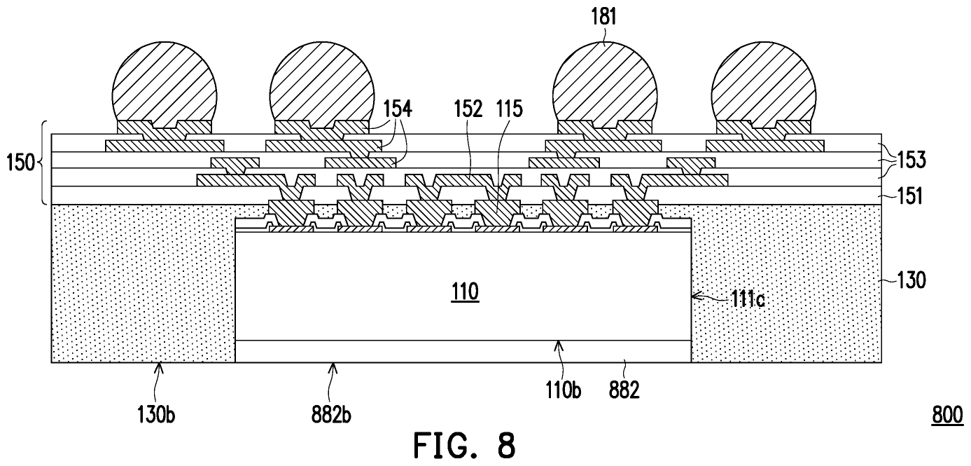

FIG. 8 is a partial cross-sectional diagram of a package structure according to the eighth embodiment of the disclosure. A package structure 800 and/or a manufacturing method thereof of the eighth embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, comparing to the package structure 100 as shown in FIG. 1, the package structure 800 as shown in FIG. 8 may further include a cover 882. Therefore, the package structure 100 may need to be considered when understanding or realizing the package structure 800 as shown in FIG. 8.

Referring to FIG. 8, the package structure 800 includes the chip 110 and the dielectric 130.

In the embodiment, the package structure 800 may further include a cover 882. The cover 882 may cover a backside 110b of the chip 110.

In the embodiment, the cover 882 may be embedded in the dielectric 130. In an embodiment, an outer surface 882b of the cover 882 may be coplanar with a bottom surface 130b of the dielectric 130.

In an embodiment, cover 882 may have a proper thermal conductivity. That is, the cover 882 may be adapted to serve as a heat sink.

In an embodiment, the cover 882 may have a proper hardness. That is, the cover 882 may be adapted to serve as a supporting component. In an embodiment, the cover 882 may be a chip backside protection layer to avoid chip damage/crack during downstream SMT (pick & place) process.

In an embodiment, the cover 882 may have proper electromagnetic wave shielding properties. That is, the cover 882 may be adapted to serve as an EMI shielding component.

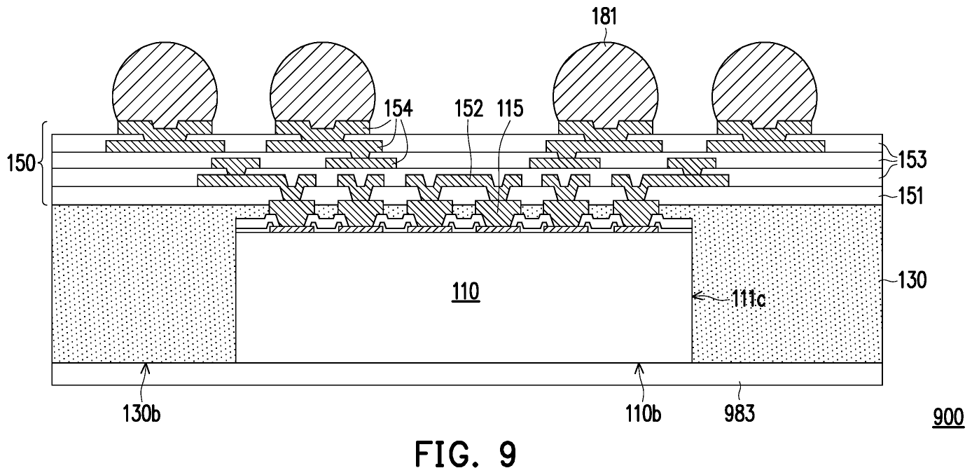

FIG. 9 is a partial cross-sectional diagram of a package structure according to the ninth embodiment of the disclosure. A package structure 900 and/or a manufacturing method thereof of the ninth embodiment are similar to the package structure 100 and/or the manufacturing method thereof of the first embodiment. Similar film layers, devices, components or areas are denoted by the same reference numerals and have similar functions, materials, or manner of formation, and the description is omitted. For example, comparing to the package structure 100 as shown in FIG. 1, the package structure 900 as shown in FIG. 9 may further include a cover 983. Therefore, the package structure 100 may need to be considered when understanding or realizing the package structure 900 as shown in FIG. 9.

Referring to FIG. 9, the package structure 900 includes the chip 110 and the dielectric 130.

In the embodiment, the package structure 900 may further include a cover 983. Cover 983 may cover the backside 110b of the chip 110.

In the embodiment, the cover 983 may further cover the dielectric 130, and the cover 983 may be disposed on the bottom surface 130b of the dielectric 130 (in the bottom of FIG. 9).

In an embodiment, the cover 983 may have the proper thermal conductivity. That is, the cover 983 may be adapted to serve as the heat sink.

In an embodiment, the cover 983 may have the proper hardness. That is, the cover 983 may be adapted to serve as the supporting component. In an embodiment, the cover 983 may be a chip backside protection layer to avoid chip damage/crack during downstream SMT (pick & place) process. Moreover, the cover 983 may have suitable mechanical properties (Tg, CTE, Modulus) to server as a structure balance layer to minimize the unit warpage of the package.

In an embodiment, the cover 983 may have the proper electromagnetic wave shielding properties. That is, cover 983 may be adapted to serve as the EMI shielding component.

It is worth noting that the package structure 800 of the eighth embodiment and/or the package structure 900 of the ninth embodiment may be similar to the package structure 100 of the first embodiment, but the disclosure is not limited thereto. In other non-illustrated embodiments, a package structure similar to the package structure 800 and/or a package structure similar to the package structure 900 may be similar to the package structures of other embodiments.

As shown in FIGS. 1I to 1K, 2, 3, 4, 5A/5B, 6A/6B, 7A/7B, 8 and 9 with the corresponding description, a package structure (100, 200, 300, 400, 500, 600, 700, 800, 900) includes a chip (100) and a dielectric (130, 230, 730). The chip includes a chip connector (115, 515, 615) disposed on an active surface (110a). The dielectric is at least disposed on the active surface of the chip. The chip connector has a top surface (115a, 515a, 617a) and a side surface (115c, 515c, 617c) connected to the top surface. The dielectric does not directly cover part of the side surface (115c1 of 115c, 515c1 of 515c, part of 617c) close to the top surface. In an embodiment, the dielectric covers remaining part of the side surface away from the top surface. In an embodiment, a slope of the side surface is substantially consistent when viewed from a cross-section of the package structure. In an embodiment, the chip further includes a substrate (111), and in a thickness direction of the package structure, the top surface of the chip connector is an outer surface of the chip connector farthest away from the substrate. In an embodiment, the top surface of the chip connector is substantially a planar surface. In an embodiment, the chip further includes a substrate (111), and in a thickness direction of the package structure, the dielectric is substantially not disposed between the chip connector and the substrate. In an embodiment, a top surface of the dielectric has a first top surface area, the first top surface area extends away from the chip connector from a contact point of the first top surface area and the chip connector, and there is a space between the first top surface area and the top surface of the chip connector. In an embodiment, a top surface of the dielectric has a first top surface area, the first top surface area extends away from the chip connector from a contact point of the first top surface area and the chip connector, and a roughness of the first top surface area is different from a roughness of the top surface of the chip connector. In an embodiment, the chip further includes a substrate (111), the chip connector comprises a first conductive layer (115s, 515s, 617s, 618s) and a second conductive layer (115p, 515p, 617p, 618p) disposed on the first conductive layer, and the first conductive layer is disposed between the second conductive layer and the substrate. In an embodiment, the dielectric directly completely covers the first conductive layer. In an embodiment, the chip further includes a substrate (111), and the dielectric further covers a side surface of the substrate.

As shown in FIGS. 1I to 1K, 2, 3, 4, 5A/5B, 6A/6B, 7A/7B, 8 and 9 with the corresponding description, a package structure (100, 200, 300, 400, 500, 600, 700, 800, 900) includes a chip (100), a dielectric (130, 230, 730), and a redistribution layer structure (150). The chip includes a semiconductor substrate (111) and a chip connector (115, 515, 615) disposed on the semiconductor substrate. The dielectric (130, 230, 730) is at least disposed on the chip. The redistribution layer structure is disposed on the chip and the dielectric. A contact point (P) where the chip connector, the dielectric, and the redistribution layer structure directly contact with each other is disposed on part of an outer planar surface (115c, 515c, 617c) of the chip connector. In an embodiment, in a thickness direction of the package structure, at least part of the redistribution layer structure does not overlap the chip. In an embodiment, in a thickness direction of the package structure, a distance between a top surface of the chip connector and the semiconductor substrate is greater than a distance between the contact point and the semiconductor substrate. In an embodiment, the outer planar surface where the contact point is disposed is not parallel to a top surface (111a) of the semiconductor substrate.

To sum up, by making the part of the dielectric close to the chip connector of the chip more concave than the chip connector, the package structure and the manufacturing method thereof according to the disclosure may simplify the manufacturing and/or achieve a high yield.

What is claimed is:

1. A package structure, comprising:
a chip, comprising a chip connector disposed on an active surface; and
a dielectric, at least disposed on the active surface of the chip, wherein:
the chip connector has a top surface and a side surface connected to the top surface;
the dielectric does not directly cover part of the side surface close to the top surface.

2. The package structure according to claim 1, wherein the dielectric covers remaining part of the side surface away from the top surface.

3. The package structure according to claim 1, wherein a slope of the side surface is substantially consistent when viewed from a cross-section of the package structure.

4. The package structure according to claim 3, wherein the chip further comprises a substrate, and in a thickness direction of the package structure, the top surface of the chip connector is an outer surface of the chip connector farthest away from the substrate.

5. The package structure according to claim 3, wherein the top surface of the chip connector is substantially a planar surface.

6. The package structure according to claim 1, wherein the chip further comprises a substrate, and in a thickness direction of the package structure, the dielectric is substantially not disposed between the chip connector and the substrate.

7. The package structure according to claim 1, wherein a top surface of the dielectric has a first top surface area, the first top surface area extends away from the chip connector from a contact point of the first top surface area and the chip connector, and there is a space between the first top surface area and the top surface of the chip connector.

8. The package structure according to claim 1, wherein a top surface of the dielectric has a first top surface area, the first top surface area extends away from the chip connector from a contact point of the first top surface area and the chip connector, and a roughness of the first top surface area is different from a roughness of the top surface of the chip connector.

9. The package structure according to claim 1, wherein the chip further comprises a substrate, the chip connector comprises a first conductive layer and a second conductive layer disposed on the first conductive layer, and the first conductive layer is disposed between the second conductive layer and the substrate.

10. The package structure according to claim 9, wherein the dielectric directly completely covers the first conductive layer.

11. The package structure according to claim 1, wherein the chip further comprises a substrate, and the dielectric further covers a side surface of the substrate.

12. A package structure, comprising:
a chip, comprising a semiconductor substrate and a chip connector disposed on the semiconductor substrate;
a dielectric, at least disposed on the chip; and
a redistribution layer structure, disposed on the chip and the dielectric, wherein a contact point where the chip connector, the dielectric, and the redistribution layer structure directly contact with each other is located on part of an outer planar surface of the chip connector.

13. The package structure according to claim 12, wherein in a thickness direction of the package structure, at least part of the redistribution layer structure does not overlap the chip.

14. The package structure according to claim 12, wherein in a thickness direction of the package structure, a distance between a top surface of the chip connector and the semiconductor substrate is greater than a distance between the contact point and the semiconductor substrate.

15. The package structure according to claim 12, wherein the outer planar surface where the contact point is disposed is not parallel to a top surface of the semiconductor substrate.

16. A manufacturing method of a package structure, comprising:
providing a chip, comprising a chip connector, wherein the chip connector has a top surface and a side surface connected to the top surface;
forming a dielectric material on the chip to directly cover the chip; and
forming a dielectric by removing part of the dielectric material to at least expose part of the side surface close to the top surface.
